(19) United States
(12) Patent Application Publication
(10) Pub. No.: US 2007/0210340 A1
(43) Pub. Date: Sep. 13, 2007

(54) GaAs power transistor

(76) Inventors: Peter J. Zampardi, Newbury Park, CA (US); Mike Sun, Thousand Oaks, CA (US)

Correspondence Address: SMITH FROHWEIN TEMPEL GREENLEE BLAHA, LLC, Two Ravinia Drive, Suite 700, ATLANTA, GA, 30346, US

(21) Appl. No.: 11/372,547

(22) Filed: Mar. 10, 2006

(51) Int. Cl. H01L 29/76

(52) U.S. Cl. 257/213

(57) ABSTRACT

A GaAs power transistor unit cell is provided with one of its transistor contacts on its bottom surface, and its other two transistor contacts on its frontside surface. In one arrangement, the GaAs power transistor unit cell has a N+ GaAs substrate that cooperates with an N− GaAs material to form a transistor collector. A collector contact is on a bottom surface of the collector, and a transistor base is provided on the collector. An emitter is arranged on the base. Accordingly, the collector contact is on the bottom of the unit cell, while a base contact and emitter contact are oriented to the frontside of the unit cell. It will be understood that the emitter and collector portions may be exchanged in other constructions. In use, the GaAs transistor unit cells are interconnected to form a GaAs power transistor, with the power transistor having externally available contacts. In one specific construction, a connection pad is provided on a laminate substrate. The GaAs power transistor is adhered and secured to the contact pad using the bottom contact, enabling a GaAs power amplifier to be easily integrated onto the laminate substrate and connected with other circuitry.

### BACKGROUND

The field of the present invention is the design, fabrication, and manufacture of power transistors. More particularly, the invention relates to a power transistor employing Gallium Arsenide (GaAs) material and processes.

Modern electronics equipment often needs efficient power transistors with good radio frequency characteristics. For example, wireless devices typically have a radio and associated circuitry generating a low-level radio frequency signal. This low-level radio frequency signal needs to be amplified for transmission from an antenna system. The use and manufacturer of power transistors is well-known, and has advanced to create highly efficient and effective power transistors. For example, power transistors may be made using a GaAs (Gallium Arsenide) material and process. The GaAs material and process has been found to create power transistors with particularly desirable radio frequency characteristics, high yields, and are cost competitive with other technologies due to their high power densities.

Referring to FIG. 10, a typical GaAs power transistor unit cell is illustrated. Multiple unit cells may be interconnected to form a power transistor, with the power transistor having contact pads for connection to a target device, such as a radio transmitter. The GaAs power transistor is formed by first depositing the epitaxial layers on the substrate and then etching to the appropriate layers, followed by depositing a metal contact for each terminal of the device. The GaAs power transistor is typically grown on a semi-insulating substrate on which an N+ GaAs contact layer (sub-collector) is deposited. This N+ sub-collector layer serves as a contact layer for the collector of the transistor. An N− GaAs collector region is deposited on top of the sub-collector layer. The base layer is then deposited atop the collector Next, the emitter layer (a wide bandgap semiconductor) is deposited. On top of this emitter layer, an emitter contacting layer, so that contact resistance can be minimized, is finally deposited. After the growth of the material, the emitter, base and collector contacts are formed by etching to the specific layers and depositing contact metals. Individual transistors are isolated from one another using an combination of mesa etches and damage implants to isolate the collectors from one another. To form a power transistor from these individual unit building blocks, interconnect metals and dielectrics are deposited to connect the individual unit cells. These allow for isolation of the various terminals (emitter, base, and collector) and also allow the devices to be connected in parallel for forming a larger power transistor device.

As shown in FIG. 10b, a GaAs wafer has many individual power transistors. Each power transistor consists of smaller building blocks that represent individual unit cell transistors. Each of these unit transistors has a top surface which has a collector contact, an emitter contact, and a base contact. The individual power transistors consume substantial space, limiting the number of power transistors which may be produced from one wafer and requiring more board space in its particular end application. It will be appreciated that other wafer configurations may be used. FIG. 10c illustrates another power transistor arrangement that uses a pair of emitter contacts, a base contact, and a collector contact. The size of these arrays is limited by the various contacting layers (in particular, unit cell collector contact space) and by the interconnects required to connect these power transistors to a package. For example, FIG. 10d shows a typical layout for a power transistor. The power transistor has an RF input pad area “a” for receiving signals for amplification. The circuitry also has ground contact pad area “e” for receiving a ground connection, as well as a control contact pad area “f” for receiving control signals in. Control signals are received from a processor or other supervisory control module within the wireless device. The control signals cooperate with control circuitry “b” for controlling amplification and signal characteristics. Amplification is done in the amplification area “c”. Amplification area “c” comprises several interconnected power transistor unit cells, each separated by an implant. The power transistor circuit also has an RF (radio frequency) out pad area “d”, for connecting the output from the power transistor to other target device circuitry, such as an antenna system.

Due to the desirability of the GaAs power transistor technology, and pressures to reduce cost and increase wafer density, there exists a need for a GaAs power transistor or amplifier that consumes less space, is more efficiently manufactured, and integrates more conveniently with other circuit technologies.

### SUMMARY

Briefly, the present invention provides a GaAs power transistor unit cell with one of its transistor contacts on its bottom surface, and its other two transistor contacts on its frontside surface. In one arrangement, the GaAs power transistor unit cell has a N+ GaAs substrate that cooperates with an N− GaAs material to form a transistor collector. A collector contact is on a bottom surface of the collector, and a transistor base is provided on the collector. An emitter is arranged on the base. Accordingly, the collector contact is on the bottom of the unit cell, while a base contact and emitter contact are oriented to the topside of the unit cell. It will be understood that the emitter and collector portions may be exchanged in other constructions. In use, the GaAs transistor unit cells are interconnected to form a GaAs power transistor, with the power transistor having externally available contacts. In one specific construction, a connection pad is provided on a laminate substrate. The GaAs power transistor is adhered and secured to the contact pad using the bottom contact, enabling a GaAs power amplifier to be easily integrated onto the laminate substrate and connected with other circuitry.

Advantageously, the disclosed GaAs unit cells enable a GaAs power transistor to be constructed that has a thicker collector area, and therefore may be operational at higher voltage levels. Also, the disclosed GaAs power transistors may be manufactured with high yield densities, as they eliminate the need for isolation implants, and have one of the transistor contacts on the bottom surface of the transistor. By placing one of the transistor contacts on the bottom side, valuable space is conserved on the top side.

Additionally, the disclosed GaAs power transistor enables a GaAs power transistor to be conveniently integrated with a CMOS or bipolar circuit. In this manner, device functionality may be readily proportioned between CMOS or bipolar components and GaAs components according to the strengths and desirability of each technology. For example, CMOS circuitry may be economically used for control and early stage amplification, and GaAs transistors may be readily integrated for final stage amplification.

### BRIEF DESCRIPTION OF THE DRAWINGS

The invention can be better understood with reference to the following figures. The components within the figures are not necessarily to scale, emphasis instead being placed upon clearly illustrating the principles of the invention. Moreover, in the figures, like reference numerals designate corresponding parts throughout the different views. It will also be understood that certain components and details may not appear in the figures to assist in more clearly describing the invention.

FIG. 1 is a block diagram of a GaAs power transistor unit cell in accordance with the present invention.

FIG. 1a is a block diagram of a GaAs power transistor formed by interconnecting multiple GaAs unit cells in accordance with the present invention.

FIG. 2 is a diagram of a wafer of GaAs power transistors in accordance with the present invention.

FIG. 3 is a block diagram of a circuit layout of a GaAs power transistor in accordance with the present invention.

FIG. 4 is a is block diagram of a module layout using a GaAs power transistor in accordance with the present invention.

FIG. 5 is a is block diagram of a circuit layout using a GaAs power transistor in accordance with the present invention.

FIG. 6 is a flowchart for making a GaAs power transistor unit cell in accordance with the present invention.

FIG. 7 is a flowchart for using a GaAs power transistor in accordance with the present invention.

FIG. 8 is a block diagram of a GaAs power transistor unit cell in accordance with the present invention.

FIG. 9 is a flowchart for making a GaAs power transistor unit cell in accordance with the present invention.

FIG. 10 is a diagram of a known GaAs power transistor unit cell, wafer, and circuit layout.

### DETAILED DESCRIPTION

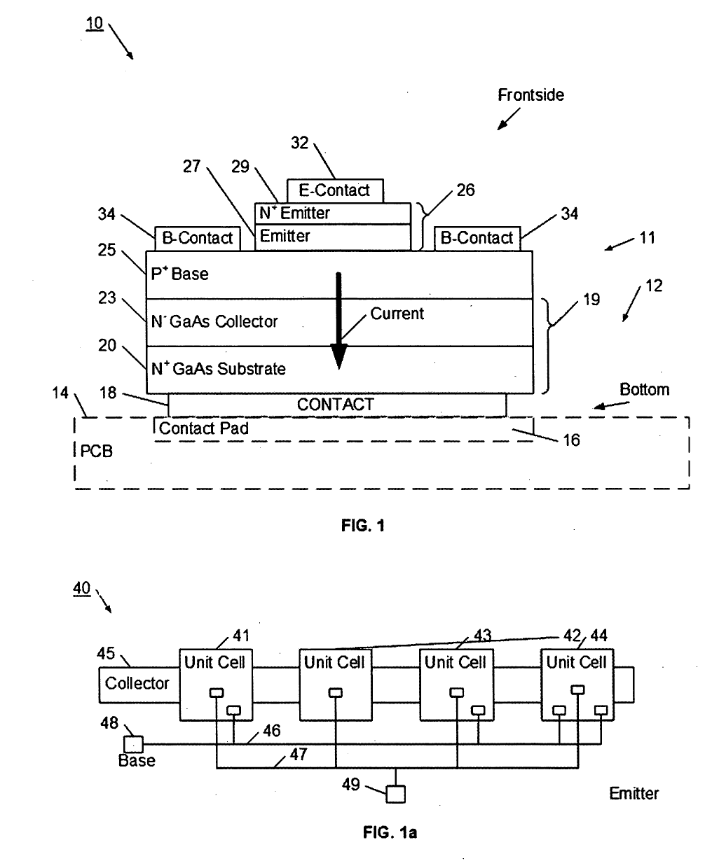

Referring now to FIG. 1, a power transistor unit cell 10 is illustrated. Power transistor unit cell 10 may be, for example, part of a power stage for an amplifier system. In one use, power transistor cell unit 10 operates as part of a final stage amplifier for a radio transceiving device. Although power transistor unit cell 10 will be described with reference to use in a wireless device, it will be appreciated that power transistor unit cell 10 may have many other uses. For example, many electronic devices, modules, and circuits have need for high quality power amplification in limited space.

Power transistor unit cell 10 typically interconnects with other unit cells to form a power transistor. The power transistor is constructed to be mounted to a laminate printed circuit board 14 or other supporting structure. In another example, the support structure may be part of an integrated circuit system, or may be associated with a multi-module component. The printed circuit board 14 has contact pad 16 constructed of a conductive material. Contact pad 16 is connected through traces on printed circuit board 14 to other parts of a device's circuitry. Typically pad 16 will be a ground connection or carry an amplified RF signal. The device support 12 receives the transistor 11. Transistor 11 is constructed with a large area contact 18 on its bottom surface. More particularly, contact 18 acts as a collector contact pad for collector 19. Collector 19 has an N+ GaAs substrate 20 for improved conductivity with contact 18. Collector 19 also has an N− GaAs collector region 23. Together, the N− GaAs collector region and the N+ GaAs substrate region form the collector for transistor 11. A base 25 is disposed on top of collector 19, with a base contact 34 electrically coupled to the base. Base contact 34 is constructed to receive an interconnect metal that is routed to a bondpad for connection to PCB traces or other device circuitry via a wirebond. An emitter 26 is deposited on base 25. More particularly, emitter 26 has an emitter region 27 with an N+ emitter region 29 for facilitating improved conduction to emitter contact 32. Emitter contact 32 is constructed to receive an interconnect metal that is routed to a bondpad for connection to PCB traces or other device circuitry with a bond wire.

Transistor 11 has several advantages over prior known power transistors. For example, transistor 11 is constructed without isolating implants associated with the collector and subcollector. In this way, the collector 19 may be made thicker to support higher voltage requirements. More particularly, prior transistor devices required the collector contact region to be recessed to connect to the sub-collector (contacting layer). This caused limitations as to the thickness of the collector. However, transistor 11 is manufactured without the need for collector implants, and therefore emitter 19 may be manufactured as thick as required. This additional thickness supports higher voltage and more efficient fabrication.

In yet another advantage, power transistor 11 may be manufactured with much higher die densities than in known processes. It has been discovered that densities may be increased three to five times over known GaAs power transistor technologies. Such density increases are enabled by two significant structural changes for transistor 11. First, transistor 11 does not need a front-side collector contact pad for connection. In this way, substantial die area is conserved as the collector contact 18 is positioned on the bottom surface of transistor 11. This also allows for the collector contact pads to be place on the back or bottom side of the wafer, saving significant frontside space. Second, transistor 11 requires no implants between transistor collectors. Some power amplifier transistor designs have multiple collector access points, and each access point requires implant separation. Instead of providing multiple collector access points separated by implants, transistor 11 simply routes the collector conduction paths to a common collector contact point on the bottom surface of the die. In this way, substantially higher densities of circuitry are enabled in the GaAs circuit layout.

FIG. 1a shows unit cells 41, 42, 43, and 44 interconnected to form a power transistor 40. Each of the unit cells 41, 42, 43, and 44 are similar to the transistor unit cell 10 discussed with reference to FIG. 1, so will not be described in detail. As illustrated, each unit cell 41, 42, 43, and 44 has a base contact and an emitter contact on its front side. Each base contact is interconnected with the other base contacts, and connects to a base contact pad 48. This base contact pad 48 may then be wirebonded or otherwise connected to other circuitry. In a similar manner, each emitter contact is interconnected with the other emitter contacts, and connect to an emitter contact pad 49. This emitter contact pad 49 may then be wirebonded or otherwise connected to other circuitry. Advantageously, the collector contact is on the backside of each of the unit cells 41, 42, 43, and 44, and so can be interconnected using a backside interconnection 45. This backside interconnection is them mechanically and electronically coupled to a pad on a target device as described with reference to FIG. 1. The unit cells may cooperate with other circuitry (not shown) to form the power transistor.

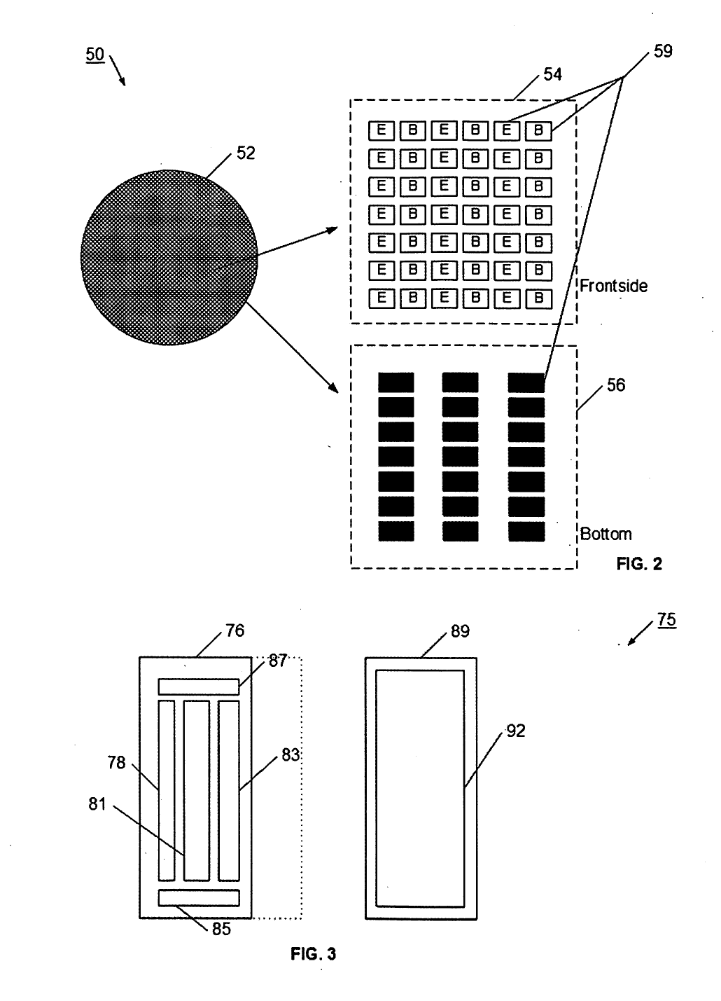

Referring now to FIG. 2, the GaAs wafer 50 is illustrated. Wafer 50 has a generally circular substrate 52 on which power transistors have been manufactured. These power transistors are similar to power transistor 40 described with reference to FIG. 1a. The process of manufacturing GaAs devices, doping, and depositing layers on die are well known, and will not be described in detail. Enlarged area 54 shows a small area from wafer 52. Enlarged area 54 shows that the upper surfaces of the GaAs die have only base and emitter contact areas, which may be routed to various bondpads. The upper surface has no collector contacts, as a collector contact pad is on the bottom surface of the die. Referring to enlarged area 56, the bottom side of wafer 52 is illustrated. Enlarged area 56 shows that a collector pad is positioned below its respective base and emitter contact pad, and may cover the entire bottom side of the GaAs die. For example, the base, emitter, and collector identified with line 59 form one power transistor similar to power transistor 40 described earlier. Wafer 50 is just one of numerous alternatives for laying out power transistors on a semiconductor GaAs substrate. It will be appreciated that those skilled in the art will recognize other patterns, relationships, and sizes for efficiently laying out a die. It will also be appreciated that other power amplification applications may require different arrangements of transistor circuitry.

Referring now to FIG. 3, a general layout 75 for power transistor circuitry is illustrated. The power transistor circuitry is typically designed in computer aided engineering software, and converted to numerous masks for the die manufacturing process. The GaAs die is manufactured and built up using known transistor manufacturing processes, so will not be described in detail. General layout 75 provides one of many possible circuit layouts, and those skilled in the art will recognize other ways to implement power transistor circuitry. It will also be appreciated that other specific applications may require different circuit layout. General circuit layout 75 has a power transistor 76 constructed on a GaAs N+ substrate. The power amplifier 76 has input contact pads 78 for receiving signals in to power amplifier 76. For example, these input signals may be a radio frequency signal from previous stage amplifier. Power transistor 76 also has control input pads 85 for receiving control signals from, for example, a processor. These control signals may adjust amplification levels or other characteristics for power transistor 76. Power transistor 76 also has ground contact pads 87 for providing a connection to ground.

Significantly, power transistor 76 does not have any collector output contact pads on its top surface. Also, since power amplifier 76 does not require implants between collector access points, the power amplification area 83 may be made much more dense and compact as compared to prior devices. Power transistor 76 may also have control circuits 81 for managing power transistor operation. It will be appreciated that the design and construction of power transistor circuitry is well-known and will not be discussed in detail.

Power transistor 76 also has a backside 89. The backside of power transistor 76 has a collector contact area 92, which may cover all or substantially all the backside area 89. In this way, all collector access points are routed vertically through the GaAs N+ substrate to the conductive collector area 92. Then, when the power transistor is mechanically coupled to a substrate, an electrical collector connection is also made.

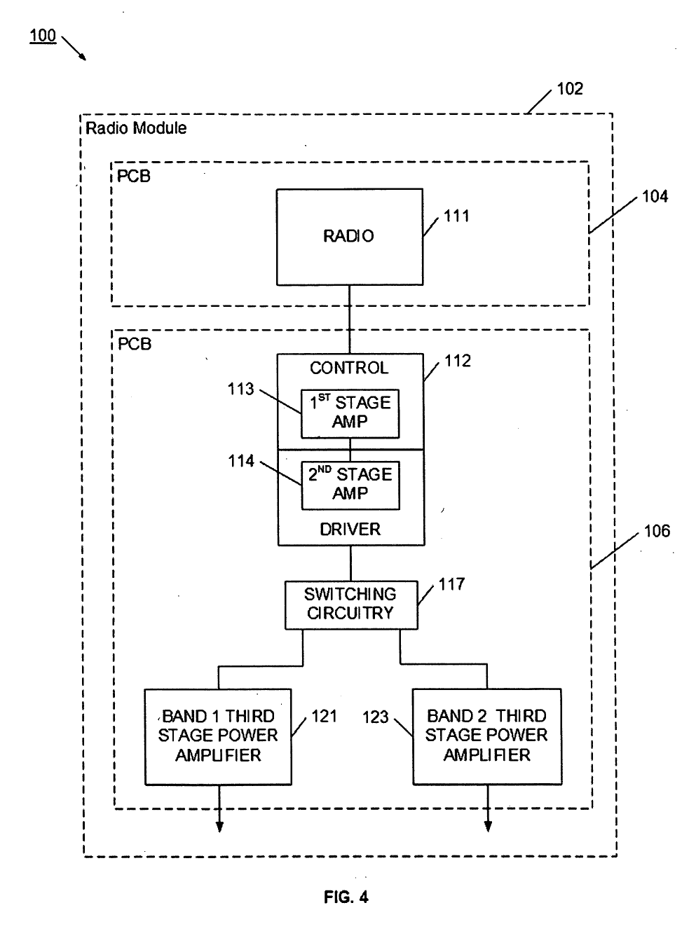

Referring now to FIG. 4, a wireless receiver circuit portion 100 is shown. Wireless receiver portion 100 may be, for example, part of a wireless device. In one example, the wireless device is a wireless handset capable of operating on two different band modes. For example, a band mode may be GSM, GPRS, CDMA, WCDMA, UMTS, PHS, PCS, or other communication band. It will be appreciated that communication standards evolve, and that other communication standards may become available. Wireless receiver portion 100 includes a radio module 102. Radio module 102 is constructed with two cooperating printed circuit board modules. A first printed circuit board module 104 has radio circuitry 111. Radio 111 may couple to an antenna and other communication modules for receiving and transmitting radio frequency signals. Radio 111 is constructed to operate according to an appropriate air interface standard. It will be appreciated that radio 111 may be acting responsive to a processor or other supervisory circuitry within the wireless device (not shown). The design and construction of wireless handsets is well-known, so will not be described herein. It will also be appreciated that the construction of wireless radio devices is also well known so will not be discussed in detail herein.

A second printed circuit board module 106 is used to amplify the low-level signal from radio 111. Printed circuit board 106 has a control and driver module 112 that, among other functions, provides preliminary amplification for the radio frequency signal. In one example, the control portion provides a first stage of amplification 113, while a driver portion provides a second stage of amplification 114. Switching circuitry 117, which operates responsive to a processor or other control circuitry, routes the preliminarily amplified signal to one of two third stage power amplifiers. Each of the third stage amplifiers is constructed for operation in a particular communication band. Third stage power amplifier 121 is constructed to operate in band one, while third stage power amplifier 123 is constructed to operate in band two. It will be understood that the wireless receiver portion 100 may be constructed to operate in only one band, or could be constructed to switch between three or more bands.

For cost efficient manufacturer of radio 111, control and driver circuitry 112, and switching circuitry 117, it is desirable that a standard bipolar or CMOS technology be employed. These technologies are relatively inexpensive to implement, provide adequate electronic characteristics, and are manufacturable with high yield production rates. However, GaAs technologies are highly desirable for improved third stage power amplifier applications. It has been found that GaAs power transistors provide particularly effective amplification at high power levels, and provide superior electronic characteristics in radio frequency use. However, GaAs manufacturing techniques are relatively expensive, and do not always offer the design flexibility available in bipolar and CMOS processes. Accordingly, wireless receiver portion 100 uses standard bipolar or CMOS technologies for radio 111, control and driver section 112, and switching circuitry 117. GaAs technology is used only for third stage power amplifiers 121 and 123. In this way, each transistor technology is efficiently used according to its desirable characteristics.

In one construction, the printed circuit board 106 is constructed to receive an integrated circuit chip which has control in driver circuits 112 and switching circuits 117. The printed circuit board 106 also has contact pads for receiving third stage power amplifier 121 and third stage power amplifier 123. In particular, the printed circuit board has large contact areas for receiving the bottom side collector of a power transistor, such as power transistor 11 described with reference to FIG. 1. The large area contact on the bottom of the power transistor is adhered to the contact pad on the printed circuit board. In one example, the power transistor is mechanically and electrically connected to the printed circuit board pad using a conductive adhesive. In another example a soldering or soldering type material may be used. It will be appreciated that other processes may be used for mounting power transistor to the printed circuit board.

Referring now to FIG. 5, another wireless receiver portion 125 is illustrated. Wireless receiver portion 125 is similar to wireless receiver portion 100 described earlier. It will be appreciated that the circuit portions of the wireless receiver may be alternatively arranged. In wireless receiver portion 125, a radio's printed circuit board 127 is provided. A radio 131, control and driver circuits 133, and switch circuits 137 are all provided on a single CMOS die. It will also be appreciated that the radio 131, control and driver 133, and switching circuitry 137 may be implemented in a bipolar technology. CMOS die 129 may be mounted on the radio printed circuit board. The control and driver circuit 133 has a first stage amplifier 134 and a second stage amplifier 135. It will be appreciated that the number and placement of amplification circuits may be adjusted according to amplification needs. The radio is constructed to operate on one of two bands. Depending on how a processor or other supervisory control circuit is set, will determine which of two power amplifiers is used to drive radio frequency signals from an antenna. The printed circuit board 127 has a first GaAs die 139 which has a band 1 third stage amplifier, and a second GaAs die 144 having a band 2 third stage power amplifier 146. In one particular example, the GaAs die has base and emitter contact pads on its upper surface, which are used to wire bond to contact areas on the printed circuit board.

Advantageously, the GaAs dies do not have collector contact pads which need to be wire bonded. Instead, the bottom surface of the GaAs die 141, 146, have a large area collector contact for electrical and mechanical connection to the printed circuit board. It will be appreciated that several alternatives exist for connecting the GaAs die to the printed circuit board. For example, the GaAs die may be adhered using a conductive adhesive, or may be soldered. Although FIGS. 4 and 5 show two constructions using third stage power amplifiers, it will be appreciated that many alternatives exist for the specific design and construction of wireless devices and their associated radio portions. It will also be appreciated that power amplifiers such as third stage power amplifiers may be used in other types of applications and other types of devices.

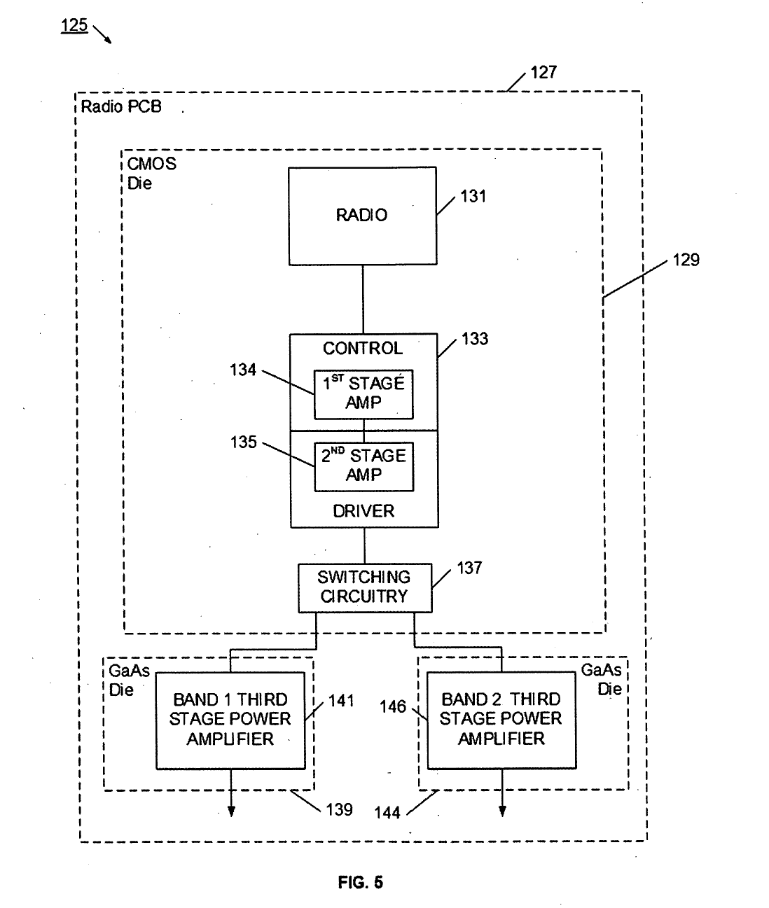

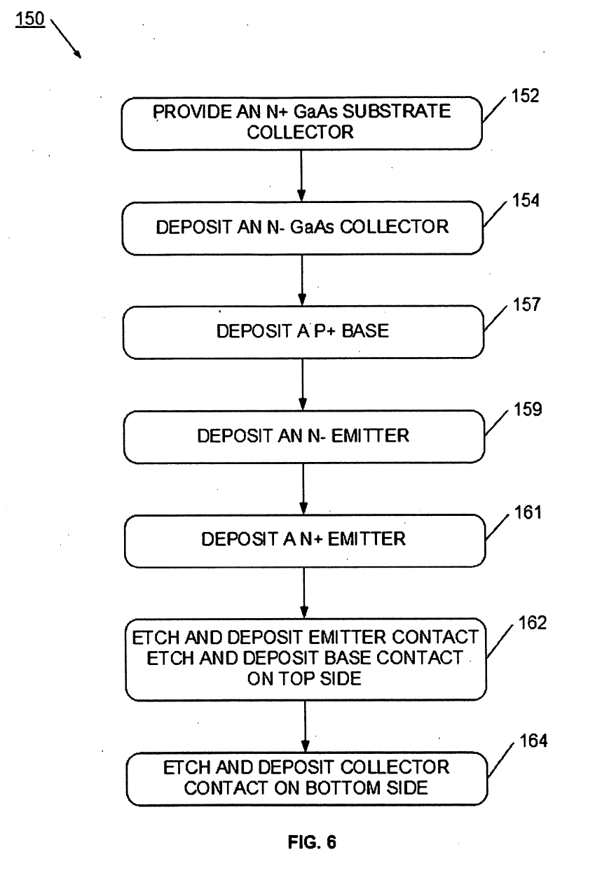

Referring now to FIG. 6, a process for manufacturing a third stage power transistor is illustrated. Method 150 starts by providing a N+ GaAs substrate subcollector as shown in block 152. Then, an N− region is deposited on its upper side as shown in block 154. A base is deposited on top of the collector as shown in block 157. An emitter is then deposited, with an N− portion as shown in block 159, and an N+ region next to an emitter for improved conductivity as shown in block 161. An emitter contact is deposited, and a base contact area is etched on the base, and a base contact is deposited. Both the emitter contact and the base contact are thereby arranged on the top surface of the transistor structure, as shown in block 162. A collector contact is deposited on the bottom side of the transistor structure as shown in block 164. The resulting power transistor thereby has a base and emitter contact on its upper surface for receiving a connection, with a large area collector pad on its bottom surface for being mechanically and electrically coupled to a support base, such as a printed circuit board or other integrated circuit.

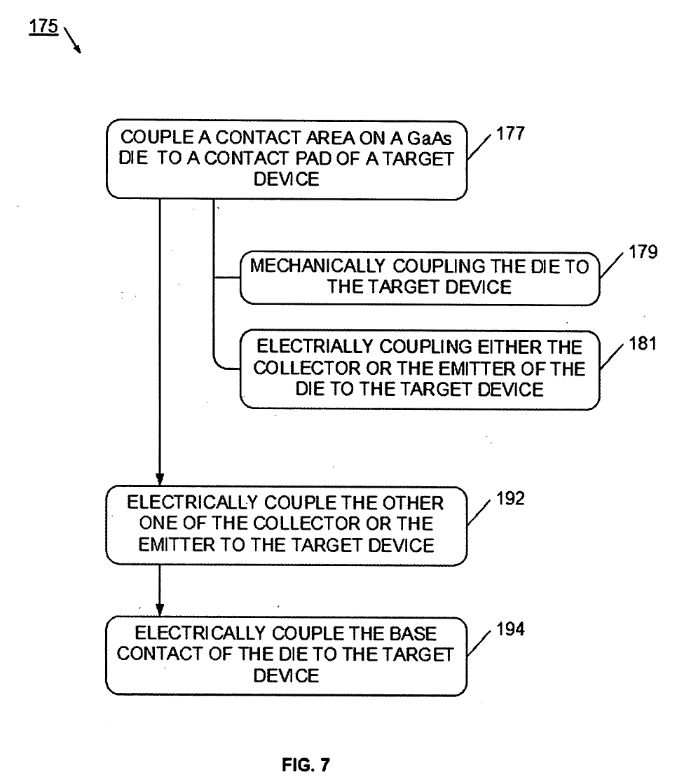

Referring now to FIG. 7, a method of installing a GaAs power transistor is illustrated. Method 175 has a GaAs power transistor die being coupled to a contact pad of a target device as shown in block 177. The target device may be, for example, a laminate printed circuit board or an integrated circuit. In one example, the target device is a radio module within a wireless mobile handset. The connection of the GaAs die to the contact pad provides a mechanically coupling of the die to the target device as shown in block 179. Also, the coupling provides an electrical coupling to the collector of the power transistor as shown in block 181. In an alternate construction of the power transistor, the emitter contact may be on the bottom surface, in which case the coupling provides an electrical coupling to the emitter.

After the GaAs die has been mechanically secured to the support target device, the other two transistor contacts are electrically connected. First, the other one of the emitter or collector is connected to the target device as shown in block 192. This connection may be, for example, by wire bonding the contact on the die to the printed circuit board or integrated circuit, or through the use of an interconnect metal. It will also be appreciated that other contact mechanisms may be used. For example, another contact area may be provided for mechanical and electrical coupling. The base is also electrically coupled to the target device, which may be through a wire bonding or other process, as shown in block 194.

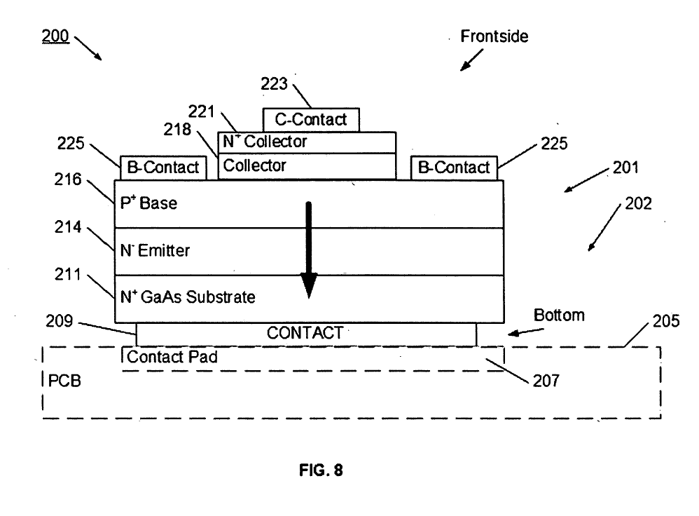

Referring now to FIG. 8, an alternative construction for power transistor unit cell 10 is illustrated. The power transistor unit cell 200 is similar to power transistor unit cell 10 described earlier, so will not be described in full detail. Power transistor unit cell 200 has a unit cell portion 201 coupled to a target base support 202. Multiple unit cells may be interconnected to form a power transistor, as described with reference to FIG. 1a. Target base 202 typically has a laminate printed circuit board 205 and a large area contact 207. A large area contact 209 is formed on the bottom surface of transistor 201. The contact is connected to an N+ GaAs substrate 211 for improved conduction characteristics. An N− emitter region 214 is formed above the substrate, and a base 216 is deposited there on. A collector is positioned on top of the base and has a main collector portion 218 and an N+ collector region 221 for improved conduction to conductor contact 223. A collector contact 223 is provided on the top surface of the transistor structure.

A base contact 225 is positioned on base 216. In transistor 201, the emitter contact 209 is exposed at the bottom, and makes electrical and mechanical contact to a contact pad 207 on a target substrate or PCB 205. In some applications, the construction of power amplifier 201 may have superior electrical characteristics as compared to a power amplifier with a collector positioned as described with reference to FIGS. 1 and 1a. However, power transistor unit cell 201 has many of the same advantages as previously described. For example, power transistor unit cell 201 has a vertical charge flow, and may be manufactured in higher densities.

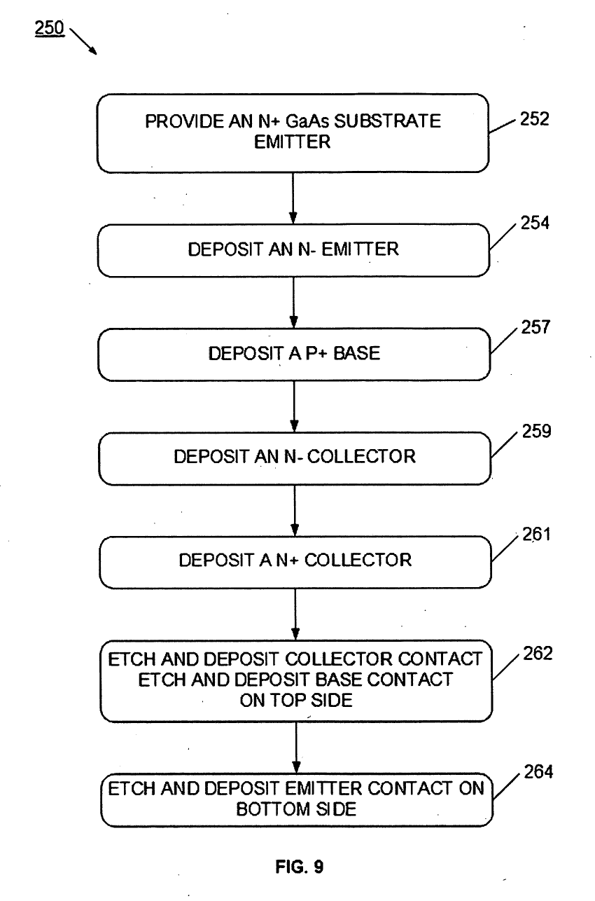

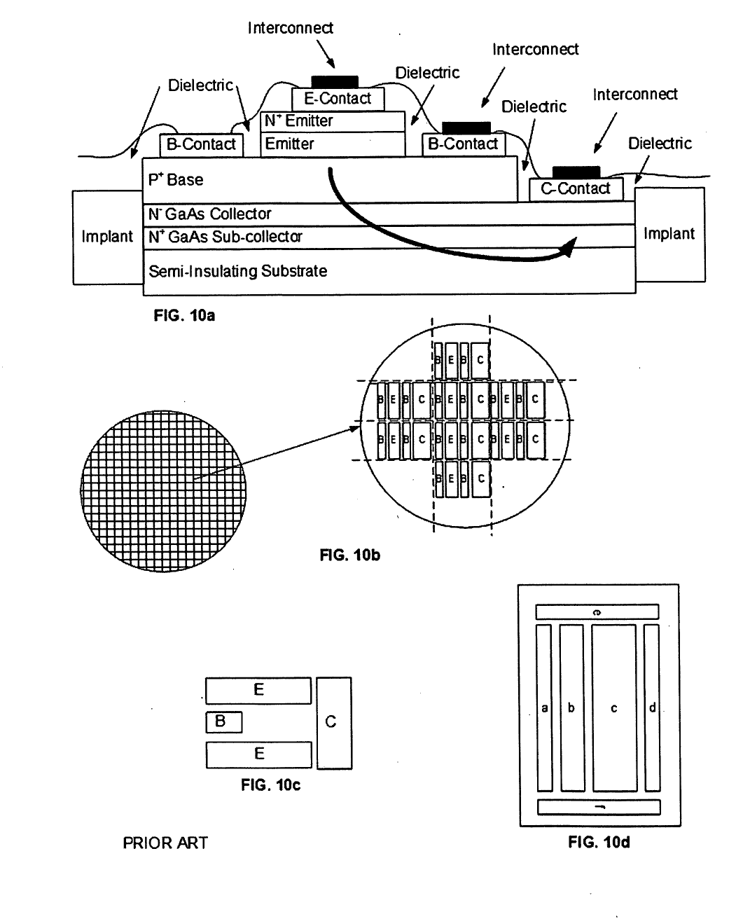

Referring now to FIG. 9, a process for manufacturing a power amplifier is described. Process 250 starts with a N+ GaAs substrate an as emitter contact. An N− emitter region is deposited on top of the substrate as shown in block 254. A base is deposited on the emitter as shown in block 257, and an N− collector region is deposited thereupon as shown in block 259. An N+ collector region is deposited for improved conduction to a collector contact as shown in block 261. A collector contact area is deposited, and a base contact area is etched on the base, and a base contact is deposited. Both the collector contact and the base contact are thereby arranged on the top surface of the transistor structure, as shown in block 262. An emitter contact area is exposed at the bottom surface of the substrate, and the emitter contact is deposited on the bottom side of the transistor structure as shown in block 264. Method 250 thereby may be used to manufacture a power transistor similar to power, transistor 201 described reference to FIG. 8.

While particular preferred and alternative embodiments of the present intention have been disclosed, it will be appreciated that many various modifications and extensions of the above described technology may be implemented using the teaching of this invention. All such modifications and extensions are intended to be included within the true spirit and scope of the appended claims.

What is claimed is:

1. A power transistor, comprising:
an N+ GaAs substrate having a first surface and a second surface;
a collector contact on the second surface of the N+ GaAs substrate;
an N− GaAs material on the first surface of the N+ GaAs substrate, the N− GaAs material and the N+ GaAs substrate cooperating to form a collector;
a P+ base arranged on the N− GaAs material, the P+ base having a base contact; and
an emitter arranged on the base, the emitter having an emitter contact.

2. The power transistor according to claim 1, wherein the second surface is a bottom surface of the power transistor die.

3. The power transistor according to claim 1, wherein:
the power transistor has a frontside and a bottom;
the base contact and the emitter contact are on the frontside; and
the collector contact is on the bottom.

4. The power transistor according to claim 1, wherein the collector contact is constructed to provide electrical coupling to a contact pad.

5. The power transistor according to claim 1, wherein the collector contact is constructed to provide mechanical attachment to a contact pad.

6. A power transistor, comprising:
an N+ GaAs substrate having a first surface and a second surface;
an emitter contact on the second surface of the N+ GaAs substrate;
an N− GaAs material on the first surface of the N+ GaAs substrate, the N− emitter material and the N+ GaAs substrate cooperating to form an emitter;
a P+ base arranged on the N− GaAs material, the P+ base having a base contact; and
a collector arranged on the base, the collector having a collector contact.

7. The power transistor according to claim 6, wherein the second surface is a bottom surface.

8. The power transistor according to claim 6, wherein:
the power transistor has a frontside and a bottom;
the base contact and the collector contact are on the frontside; and
the emitter contact is on the bottom.

9. The power transistor according to claim 6, wherein the emitter contact is constructed to provide electrical coupling to a contact pad.

10. The power transistor according to claim 6, wherein the emitter contact is constructed to provide mechanical attachment to a contact pad.

11. A transistor unit cell, comprising:
a GaAs layer having a first surface and a second surface;
a collector contact coupled to the first surface;
a base material on the second surface;
an emitter material on the base.

12. A transistor unit cell, comprising:
a GaAs layer having a first surface and a second surface;
an emitter contact coupled to the first surface;
a base material on the second surface;
a collector material on the base.

13. A method of using a power transistor, the power transistor having a base contact, an emitter contact, and a collector contact, comprising:
mechanically securing the power transistor to a support surface using one of contacts;
electrically connecting the other two contacts to the support surface; and
wherein the mechanical connection of the one contact also provides an electrical connection.

14. The method according to claim 13, wherein the attaching step includes using a conductive adhesive to attach the one contact to the support surface.

15. The method according to claim 13, wherein the attaching step includes attaching the one contact to a contact pad on a printed circuit board.

16. The method according to claim 13, wherein the one contact is the collector contact and the other two contacts are the emitter contact and the base contact.

17. The method according to claim 13, wherein the one contact is the emitter contact and the other two contacts are the collector contact and the base contact.

18. An electronic device, comprising:
a support surface;
CMOS or bipolar circuitry on the support surface;
a contact pad on the support surface and electrically coupled to the CMOS or bipolar circuitry;
a GaAs power transistor contact secured to the contact pad; and
wherein the contact pad is also electrically coupled to the power transistor.

19. The electronic device according to claim 18, wherein the support surface is a printed circuit board.

20. The electronic device according to claim 18, wherein the transistor contact pad is the transistor's collector contact.

21. The electronic device according to claim 20, wherein the transistor's base contact and emitter contact are electrically coupled to the CMOS or bipolar circuitry.

22. The electronic device according to claim 18, wherein the transistor contact pad is the transistor's emitter contact.

23. The electronic device according to claim 22, wherein the transistor's base contact and collector contact are electrically coupled to the CMOS or bipolar circuitry.

24. A radio circuit amplifier portion, comprising:
CMOS or bipolar components arranged as an early stage amplification circuitry;
a power stage amplification section;
a contact pad in the power stage amplification section, the contact pad being electrically coupled to the early stage amplification circuitry;
a GaAs power transistor constructed with a single transistor contact on its bottom surface;
wherein the transistor contact is secured to the contact pad.

25. The radio circuit according to claim 24, where the transistor contact is a collector contact, and a base contact and emitter contact are arranged on the top surface of the GaAs power transistor.

26. The radio circuit according to claim 24, where the transistor contact is an emitter contact, and a base contact and collector contact are arranged on the top surface of the GaAs power transistor.

27. The radio circuit according to claim 24, wherein the early stage amplification circuitry includes control circuitry providing a first stage of amplification.

28. The radio circuit according to claim 27, wherein the early stage amplification circuitry includes driver circuitry providing a second stage of amplification.

29. The radio circuit according to claim 28, wherein the GaAs transistor provides a third stage of amplification.

29. The radio circuit according to claim 24, wherein the GaAs transistor constructed to operate according to a first wireless communication standard.

30. The radio circuit according to claim 24, further including:
a second contact pad in the power stage amplification section, the second contact pad being electrically coupled to the early stage amplification circuitry;
a second GaAs power transistor constructed with a single second transistor contact on its bottom surface;
wherein the second transistor contact is secured to the second contact pad.

31. The radio circuit according to claim 30, wherein the GaAs transistor is constructed to operate according to a wireless communication standard, and the second GaAs transistor is constructed to operate according to a different wireless communication standard.

32. The radio circuit according to claim 31, further including a switch for selection which one of the GaAs power amplifiers is electrically coupled to the early stage amplification circuitry.
